(19) United States
(12) Patent Application Publication
(10) Pub. No.: US 2024/0313758 A1
(43) Pub. Date: Sep. 19, 2024

(54) Gate Clamping Circuit for Driving Wide Bandgap Power Device

(71) Applicant: The Hong Kong University of Science and Technology, Hong Kong (CN)

(72) Inventors: Jing CHEN, Hong Kong (CN); Ji SHU, Hong Kong (CN)

(21) Appl. No.: 18/605,836

(22) Filed: Mar. 15, 2024

Related U.S. Application Data
(60) Provisional application No. 63/490,779, filed on Mar. 17, 2023.

(51) Int. Cl. H03K 17/081

(52) U.S. Cl. CPC H03K 17/081

(57) ABSTRACT

A gate clamping circuit for driving a wide bandgap (WBG) device is provided. The gate clamping circuit comprises: a semiconductor switching device having a high side terminal connected to a gate of the WBG device; and a low side terminal connected to a source of the WBG device; a clamping resistor having a first end connected to a negative power supply terminal of a driver chip; and a second end connected to a control terminal of the semiconductor switching device; and a clamping capacitor having a first end connected to the second end of the clamping resistor; and a second end connected to the low side terminal of the semiconductor switching device; wherein the gate clamping circuit is configured to clamp negative voltage spike generated at the gate of the WBG device to suppress overstress of the gate of the WBG device when a negative off-state gate voltage is applied.

### CROSS-REFERENCE TO RELATED APPLICATIONS

The present application claims priority from the U.S. Provisional Patent Application No. 63/490,779 filed Mar. 17, 2023. The disclosure of which is incorporated herein by reference in its entirety.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The present invention generally relates to voltage clamping technology. More specifically the present invention relates to a gate clamping circuit for clamping negative spikes to suppress voltage overstress of a gate of a wide bandgap device when a negative OFF-state gate voltage is applied to the gate of the wide bandgap device.

### BACKGROUND OF THE INVENTION

Wide bandgap (WBG) power devices, such as Silicon Carbide (SiC) power metal-oxide-semiconductor field-effect transistors (MOSFETs) and gallium nitride (GaN) high-electron-mobility transistors (GaN HEMTs), can be operated at higher frequencies and higher temperatures than the traditional Si-based power devices of similar voltage and current ratings, thereby becoming the devices of choice in many high-efficiency and high-power-density converters. To operate the WBG power devices at high speeds appropriately, however, the parasitic inductances, especially those in the gate loop, need to be carefully managed.

First, the parasitic inductance impedes the gate current during the switching transient, thereby slowing down the switching speed and increasing the switching loss. Second, the parasitic inductance in series with the gate capacitance may induce gate-loop oscillation, which could lead to false turn-on during the switching process in view of the relatively low threshold voltages of some commercial WBG power devices. Third, the parasitic inductance could also lead to considerable positive and negative gate voltage spikes on the OFF-state device when adjacent devices are switching (also known as crosstalk). The positive gate voltage spikes could also lead to false turn-on, whereas the negative gate voltage spikes could overstress the gate as the minimum allowed gate voltages of mainstream WBG power devices (especially SiC MOSFETs) are limited, usually in the range of −3 to −10 V.

One solution to suppress the false turn-on is to use a gate driver with a Miller-clamping function to suppress the crosstalk-induced gate spikes. However, Miller clamp cannot address the other two issues caused by the parasitic inductance, i.e., the reduced switching speed and oscillation-induced false turn-on. In addition, the performance of Miller clamp could be compromised by the parasitic inductance during the fast switching transient of WBG power devices.

Another solution is to use a negative OFF-state gate voltage to turn off the device. The negative OFF-state gate voltage creates a wider margin below threshold voltage to accommodate the gate voltage spikes/ringing induced by crosstalk and oscillation, so that the false turn-on can be suppressed. However, from the reliability angle, especially when the negative gate spike induced by the crosstalk is superimposed during the falling edge of the drain-source voltage, the negative OFF-state gate voltage could lead the gate bias getting into the unsafe range, thus causing gate voltage overstress.

### SUMMARY OF THE INVENTION

It is one objective of the present invention to provide a gate clamping circuit for driving a wide bandgap device. The gate clamping circuit can clamp negative voltage spikes effectively when the wide bandgap device is at high switching speed, thereby protecting the gate of the wide bandgap device from voltage overstress when a negative OFF-state gate voltage is applied.

In accordance with a first aspect of the present invention, a gate clamping circuit for driving a wide bandgap device is provided. The wide bandgap device may be a SiC MOSFET having a gate, a drain, and a source. The gate clamping circuit comprises: a semiconductor switching device having a high side terminal connected to a gate of the wide bandgap device; and a low side terminal connected to a source of the wide bandgap device; a clamping resistor having a first end connected to the negative power supply terminal of a driver chip; and a second end connected to a control terminal of the semiconductor switching device; and a clamping capacitor having a first end connected to the second end of the clamping resistor; and a second end connected to the low side terminal of the semiconductor switching device; wherein the gate clamping circuit is configured to clamp negative voltage spike generated at the gate of the wide bandgap device to protect the gate of the wide bandgap device from voltage overstress when a negative off-state gate voltage is applied.

According to a second aspect of the present invention, a gate clamping driver circuit for driving a wide bandgap device. The gate clamping driver circuit comprises: a driver chip having at least a driving terminal, a negative power supply terminal, a positive power supply terminal and a ground reference terminal; a driving resistor having a first end connected to the driving terminal of the driver chip, and a second end connected to a gate of the wide bandgap device; and a gate clamping circuit according to the first aspect of the present invention.

In one embodiment of the present invention, the gate clamping circuit includes: a semiconductor switching device having a high side terminal connected to the gate of the wide bandgap device; and a low side terminal connected to the source of the wide bandgap device; a clamping resistor having a first end connected to the negative power supply terminal of the driver chip; and a second end connected to a control terminal of the semiconductor switching device; and a clamping capacitor having a first end connected to the second end of the clamping resistor; and a second end connected to the low side terminal of the semiconductor switching device.

In one embodiment of the present invention, the semiconductor switching device is a high-electron-mobility-transistor (HEMT) having a drain being the high side terminal of the semiconductor switching device; a source being the low side terminal of the semiconductor switching device; and a gate being the control terminal of the semiconductor switching device.

In one embodiment of the present invention, the HEMT is a gallium nitride (GaN) HEMT.

In one embodiment of the present invention, the GaN HEMT is enhancement-mode (E-mode) GaN HEMT.

In one embodiment of the present invention, the E-mode GaN HEMT has a rated voltage higher than the ON-state gate voltage of the wide bandgap device to be driven, e.g., 20 V,

In one embodiment of the present invention, the E-mode GaN HEMT has a rated current higher than the current flowing through the gate driver circuit during the crosstalk event, e.g., 0.1 A.

In one embodiment of the present invention, the clamping resistor has a resistance value in a range of 1 Ω-10000 Ω,

In one embodiment of the present invention, the clamping capacitor has a capacitance value higher than 0.1 nF.

In one embodiment of the present invention, the clamping resistor and the clamping capacitor can be monolithically integrated with the E-mode GaN HEMT.

### BRIEF DESCRIPTION OF THE DRAWINGS

Embodiments of the invention are described in more details hereinafter with reference to the drawings, in which:

FIG. 1 shows a circuit diagram of a gate clamping driver circuit for driving a MOSFET in accordance with one embodiment of the present invention.

FIGS. 2A and 2B show the operation principle of a gate clamping circuit (GCC) in accordance with one embodiment of the present invention.

FIGS. 3A and 3B show a simplified working principle and the SiC MOSFET gate voltage waveform with the GCC.

FIGS. 4A and 4B show the 800-V half-bridge double pulse test (DPT) set-up used to test the performance of GCC. FIG. 4A shows the current flow and change of V_{DS} when high side switch is turned on. FIG. 4B shows the current flow and change of V_{DS} when high side switch is turned off.

FIGS. 5A and 5B show the DUT's V_{DS} and Vos waveforms during one switching cycle with a V_{off}=−4 V with and without the GCC, respectively.

FIGS. 6A and 6B show the DUT's V_{DS} and Vos waveforms under a negative OFF-state gate voltage (V_{off}) of −5 V at different slew rates with and without the GCC, respectively.

FIG. 7 shows negative gate spike amplitude with and without GCC at different slew rate with a negative OFF-state gate voltage (V_{off}) of −5 V.

FIG. 8 shows the DUT slew rates against different load current under a negative OFF-state gate voltage (V_{off}) of −5 V with and without GCC.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

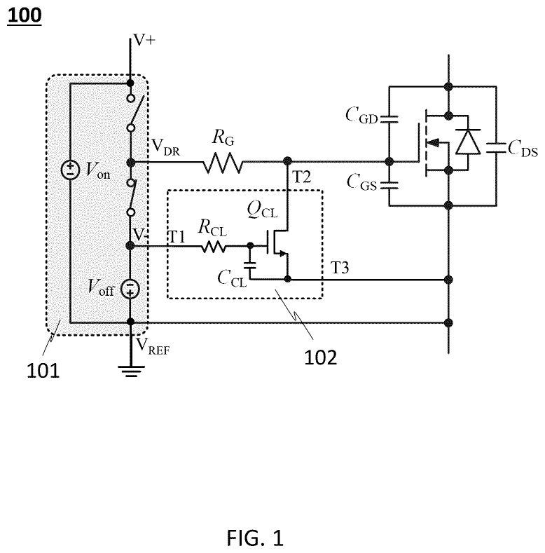

FIG. 1 shows a circuit diagram of a gate clamping driver circuit 100 for driving a MOSFET in accordance with one embodiment of the present invention. The MOSFET may be a SiC MOSFET having a gate, a drain and a source. As shown, the gate clamping driver circuit 100 comprises a driver chip 101; a driving resistor R_{G}; and a gate clamping circuit (GCC) 102.

The driver chip 101 has at least a driving terminal V_{DR}, a negative power supply terminal V−, a positive power supply terminal V+ and a reference terminal V_{REF}. The driving resistor R_{G} has a first end connected to the driving terminal of the driver chip, and a second end connected to a gate of the MOSFET. The GCC 102 has a first terminal T1 connected to the negative power supply terminal V− of the driver chip; a second terminal T2 connected to the gate of the MOSFET; and a third terminal T3 connected to the source of the MOSFET.

The GCC 102 is configured to clamp negative voltage spike generated at the gate of the MOSFET to protect the gate of the MOSFET from voltage overstress when a negative off-state gate voltage is applied.

In one embodiment, the GCC 102 includes a semiconductor switching device Q_{CL} having a high side terminal connected to the gate of the MOSFET; and a low side terminal connected to the source of the MOSFET; a clamping resistor R_{CL} having a first end connected to the negative power supply terminal of the driver chip; and a second end connected to a control terminal of the switching device Q_{CL}; and a clamping capacitor C_{CL} having a first end connected to the second end of the clamping resistor; and a second end connected to the low side terminal of the switching device Q_{CL}.

Preferably, the clamping resistor R_{CL} has a resistance value in a range of 1 Ω-10000Ω. The clamping capacitor C_{CL} has a capacitance value higher than 0.1 nF.

Preferably, the semiconductor switching device Q_{CL} is a high-electron-mobility-transistor (HEMT) having a drain being the high side terminal of the semiconductor switching device; a source being the low side terminal of the semiconductor switching device; and a gate being the control terminal of the semiconductor switching device.

Preferably, the HEMT Q_{CL} is an enhancement-mode (E-mode) gallium nitride (GaN) HEMT having a rated voltage higher than the on-state gate voltage of the wide bandgap device, e.g., 20 V; and a rated current higher than the current flowing through the gate circuit, e.g., 0.1 A.

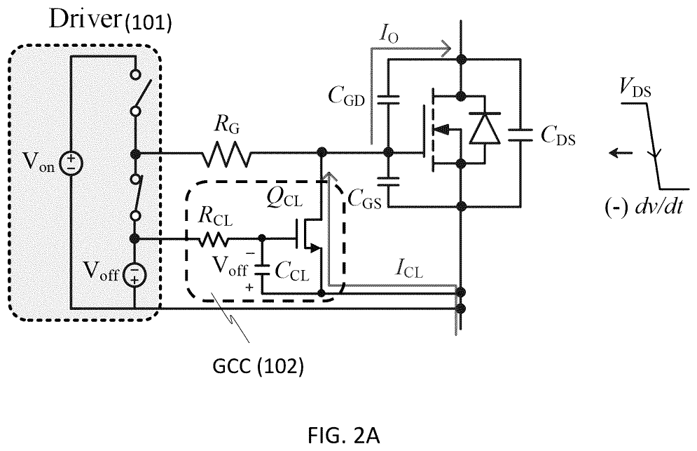

FIGS. 2A and 2B show the operation principle of the GCC, the gate of HEMT is fixed to the negative power rail of the SiC MOSFET driver through a resistor R_{CL} without the need of an additional driver for the GaN HEMT Q_{CL}. Preferably, the resistor R_{CL} is applied to prevent possible oscillation on the gate voltage of Q_{CL} during the start-up and switching process. A clamping capacitor C_{CL} is connected across the gate and source of HEMT Q_{CL} to ensure HEMT Q_{CL} is always in OFF state with a stable negative V_{GS}, which is equal to the V_{off} of the SiC MOSFET. Preferably, the gate-source capacitor C_{CL} has a capacitance higher than 0.1 nF.

As shown in FIG. 2B, the clamping voltage V_{CL} of the GCC is the reverse conduction turn-on voltage of HEMT. When a negative spike occurs, the HEMT Q_{CL} will be reversely turned-on if the spike voltage amplitude exceeds V_{CL}. As a result, as shown in FIG. 2A, most of the crosstalk induced current I_{O} will be diverted into the HEMT Q_{CL}, i.e., the current I_{CL} shown in FIG. 2A. Hence the negative gate voltage spikes of SiC MSOFET can be clamped at the clamping voltage V_{CL}.

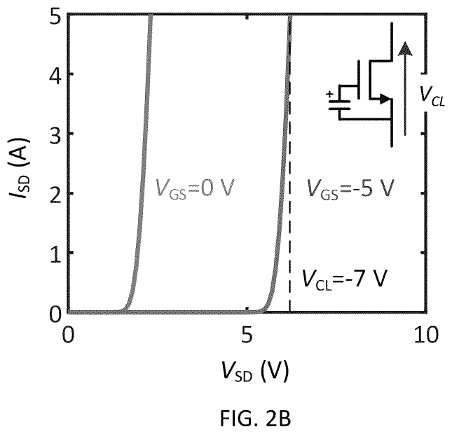

FIGS. 3A and 3B show a simplified working principle and the SiC MOSFET gate voltage waveform with the GCC. In the GCC, the GaN HEMT is always in OFF state until negative voltage spikes reversely turn it on. Thus, the GCC is operated as a diode with high voltage drop connected between the gate and source of SiC MOSFET, as shown in FIG. 3A. And the clamped SiC MOSFET gate voltage waveform is shown in FIG. 3B.

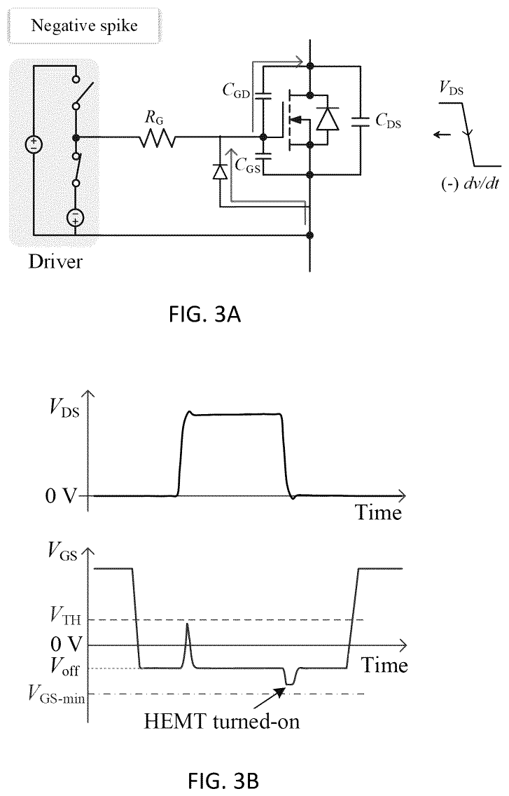

FIGS. 4A and 4B show the 800-V half-bridge double pulse test (DPT) set-up used to test the performance of GCC. Two identical SiC MOSFETs with identical driver circuits 400A and 400B are applied into the set-up shown in FIGS. 4A and 4B. The signals of the low-side device under test (DUT) are monitored. Flux cancellation and wide traces are applied in the testing circuit to minimize the gate loop parasitic inductance. A gate resistor of 4.3 Ω60 is used for both turn-on and turn-off processes. In the DPT set-up, the DUT is always in OFF state. As shown in FIG. 4A, when the high-side (HS) switch is turned-on, the DUT's V_{DS} will rise to 800 V with a positive dv/dt that could trigger a false turn-on event. As shown in FIG. 4B, when the HS switch is turned-off, the DUT's V_{DS} will fall to zero with a negative dv/dt, hence the negative gate voltage spike event can be tested.

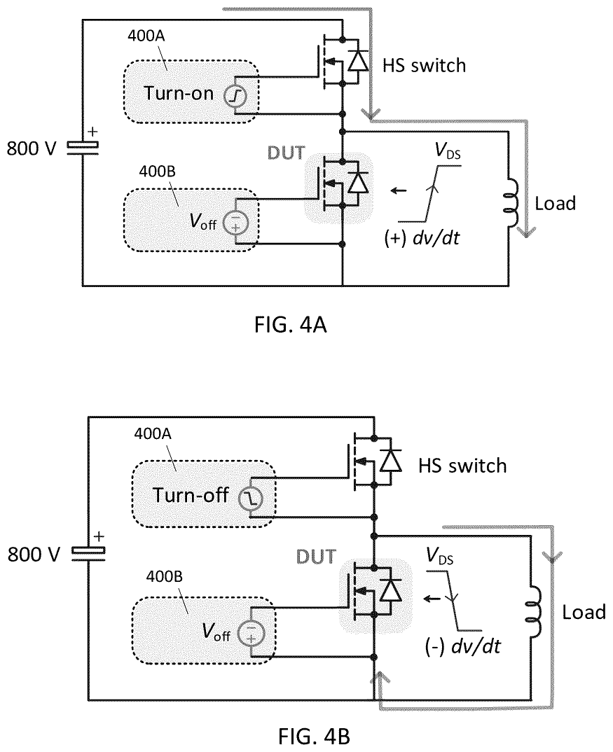

FIGS. 5A and 5B show the DUT's V_{DS} and V_{DS} waveforms during one switching cycle with a V_{off}=−4 V with and without the GCC, respectively. As shown in FIG. 5A, without the GCC, the negative spike exceeds the minimum transient gate voltage V_{GS-min} (−10 V) although gate loop parasitic inductance is minimized (V_{GS-min} of most commercial SiC MOSFETs are between −4 V and −10 V). As shown in FIG. 5B, with the GCC, the negative spike is successfully clamped. Considering the positive peak is still close to the SiC MOSFET's threshold voltage V_{TH}, a more negative V_{off} is necessary to fully avoid false turn-on.

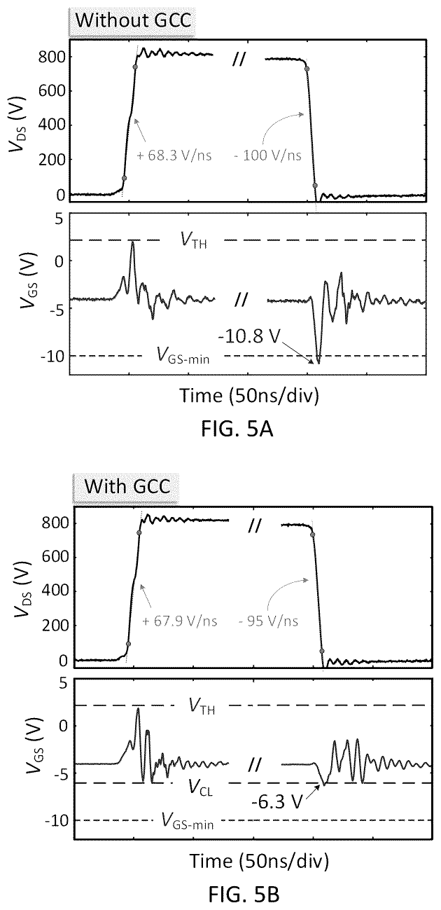

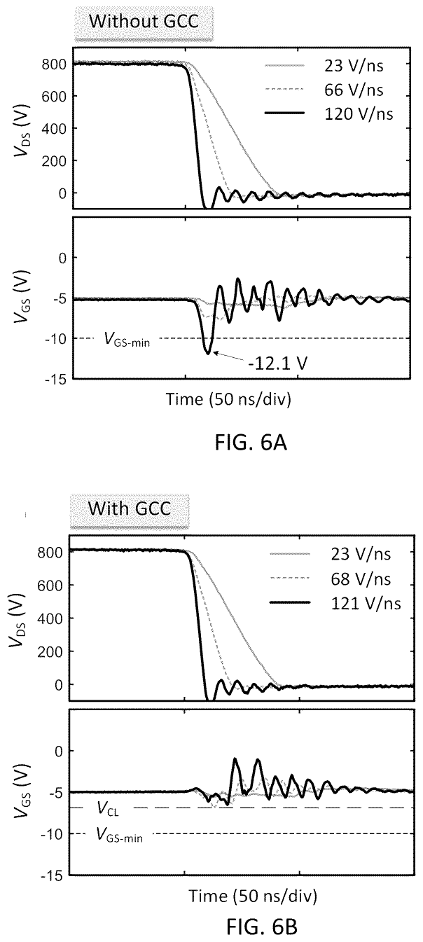

FIGS. 6A and 6B show the DUT's V_{DS} and V_{DS} waveforms under a V_{off} of −5 V at different slew rates with and without the GCC, respectively. FIG. 7 shows negative gate spike amplitude with and without GCC at different slew rate with V_{off}=−5 V. The V_{off} of −5 V is selected because it is the minimum static gate voltage of most commercial SiC MOSFETs. It can be seen that the GCC has superior clamping performance under different slew rates.

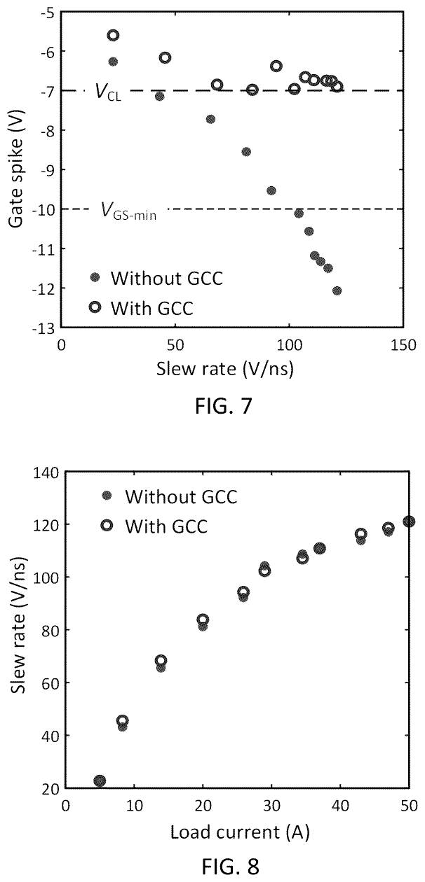

FIG. 8 shows the DUT slew rates against different load current under a V_{off} of −5 V with and without GCC. The overlapping results indicates that the switching speed of the SiC MOSFET is not affected by the GCC, thanks to the low output capacitance of the lateral GaN HEMT.

While the present disclosure has been described and illustrated with reference to specific embodiments thereof, these descriptions and illustrations are not limiting. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. Modifications may be made to adapt a particular situation, material, composition of matter, method, or process to the objective and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

What is claimed is:

1. A gate clamping circuit for driving a wide bandgap device, comprising:
a semiconductor switching device having a high side terminal connected to a gate of the wide bandgap device; and a low side terminal connected to a source of the wide bandgap device;
a clamping resistor having a first end connected to a negative power supply terminal of a driver chip; and a second end connected to a control terminal of the semiconductor switching device; and
a clamping capacitor having a first end connected to the second end of the clamping resistor; and a second end connected to the low side terminal of the semiconductor switching device;
wherein the gate clamping circuit is configured to clamp negative voltage spike generated at the gate of the wide bandgap device when a negative off-state gate voltage is applied to suppress voltage overstress of the gate of the wide bandgap device.

2. The gate clamping circuit according to claim 1, wherein the semiconductor switching device is a high-electron-mobility-transistor (HEMT) having a drain being the high side terminal of the semiconductor switching device; a source being the low side terminal of the semiconductor switching device; and a gate being the control terminal of the semiconductor switching device.

3. The gate clamping circuit according to claim 2, wherein the HEMT is a gallium nitride (GaN) HEMT.

4. The gate clamping circuit according to claim 3, wherein the GaN HEMT is enhancement-mode (E-mode) GaN HEMT.

5. The gate clamping circuit according to claim 4, wherein the E-mode GaN HEMT has a rated voltage higher than an on-state gate voltage of the wide bandgap device.

6. The gate clamping circuit according to claim 4, wherein the E-mode GaN HEMT has a rated current higher than a current flowing through the gate driver circuit.

7. The gate clamping circuit according to claim 1, wherein the clamping resistor has a resistance value in a range of 1 Ω-10000 Ω.

8. The gate clamping circuit according to claim 1, wherein the clamping capacitor has a capacitance value equal to or higher than 0.1 nF.

9. A gate clamping driver circuit for driving a wide bandgap device, comprising:
a driver chip having at least a driving terminal, a negative power supply terminal, a positive power supply terminal, and a ground reference terminal;
a driving resistor having a first end connected to the driving terminal of the driver chip, and a second end connected to a gate of the wide bandgap device; and
a gate clamping circuit of claim 1.

10. The gate clamping driver circuit according to claim 9, wherein the gate clamping circuit includes:
a semiconductor switching device having a high side terminal connected to the gate of the wide bandgap device; and a low side terminal connected to the source of the wide bandgap device;
a clamping resistor having a first end connected to the negative power supply terminal of the driver chip; and a second end connected to a control terminal of the semiconductor switching device; and
a clamping capacitor having a first end connected to the second end of the clamping resistor; and a second end connected to the low side terminal of the semiconductor switching device.

11. The gate clamping driver circuit according to claim 10, wherein the semiconductor switching device is a high-electron-mobility-transistor (HEMT) having a drain being the high side terminal of the semiconductor switching device; a source being the low side terminal of the semiconductor switching device; and a gate being the control terminal of the semiconductor switching device.

12. The gate clamping driver circuit according to claim 11, wherein the HEMT is a gallium nitride (GaN) HEMT.

13. The gate clamping driver circuit according to claim 12, wherein the GaN HEMT is enhancement-mode (E-mode) GaN HEMT.

14. The gate clamping driver circuit according to claim 13, wherein the E-mode GaN HEMT has a rated voltage higher than 20 V.

15. The clamping driver circuit according to claim 13, wherein the E-mode GaN HEMT has a rated current higher than 0.1 A.

16. The clamping driver circuit according to claim 9, wherein the clamping resistor has a resistance value in a range of 1 Ω-10000 Ω.

17. The clamping driver circuit according to claim 9, wherein the clamping capacitor has a capacitance value higher than 0.1 nF.
